(19) United States
(12) Patent Application Publication
(10) Pub. No.: US 2026/0098691 A1
(43) Pub. Date: Apr. 9, 2026

(54) HEAT DISSIPATION DEVICE

(71) Applicant: KOREA ADVANCED INSTITUTE OF SCIENCE AND TECHNOLOGY, Daejeon (KR)

(72) Inventors: Sung Jin KIM, Daejeon (KR); Young Jin LEE, Daejeon (KR); Juhyeon LEE, Daejeon (KR)

(73) Assignee: KOREA ADVANCED INSTITUTE OF SCIENCE AND TECHNOLOGY, Daejeon (KR)

(21) Appl. No.: 18/998,426

(22) PCT Filed: Jul. 31, 2023
(86) PCT No.: PCT/KR2023/011129

§ 371 Date: Jan. 24, 2025

(30) Foreign Application Priority Data
Dec. 26, 2022 (KR) 10-2022-0184014
Jul. 3, 2023 (KR) 10-2023-0085692

(51) Int. Cl. F28F 3/08

(52) U.S. Cl. CPC F28F 3/08

(57) ABSTRACT

A heat dissipation device is disclosed. The heat dissipation device according to one aspect of the present disclosure includes: a heat dissipation part having a heat dissipation structure formed on one surface thereof for dissipating heat received from a heat-generating element; and a fluid inlet and outlet section disposed on one surface of the heat dissipation part, with an inlet path formed with an inlet opening that is open toward the surface of the heat dissipation part to receive fluid from both sides, and an outlet path formed with an outlet opening that is open toward the surface of the heat dissipation part to discharge the fluid. The fluid supplied from both directions of the fluid inlet and outlet section is supplied through the inlet opening of the inlet path to the heat dissipation structure of the heat dissipation part to absorb heat and is then discharged through the outlet opening of the outlet path back into the fluid inlet and outlet section.

### TECHNICAL FIELD

The present disclosure relates to a heat dissipation device. More specifically, the present disclosure pertains to a heat dissipation device configured to enhance cooling performance through efficient fluid supply and discharge.

### BACKGROUND

The fourth industrial revolution has ushered in an era of hyper-connectivity and hyper-intelligence. This transformation has been made possible by advances in computing and information communication technologies. With these technological advancements, there has been a trend towards ultra-high integration of devices such as IGBTs, RF devices, and GaN devices, resulting in heat fluxes in electronic devices exceeding 1,000 W/cm². Furthermore, as SiP (System in Package) technology is being applied to enhance spatial utilization within packages by stacking electronic devices in 3D, the heat flux at the package level is rapidly increasing and is expected to reach around 1,500 W/cm² within the next five years. Accordingly, there is a demand for the development of heat dissipation devices with high-performance heat dissipation capabilities.

FIGS. 1 and 2 depict heat dissipation devices according to prior art.

Referring to FIG. 1, the conventional heat dissipation device typically involves arranging multiple heat dissipation fins 12 in parallel on one surface of an electronic device 10 and performing cooling by passing fluid over them.

Referring to FIG. 2, in conventional heat dissipation devices, as the fluid moves from the inlet side to the outlet side, its temperature rises, causing uneven heat dissipation across the electronic device 10.

### SUMMARY

An embodiment of the present disclosure aims to provide a heat dissipation device that enhances heat dissipation performance through efficient fluid supply and discharge.

According to one aspect of the present disclosure, there is provided a heat dissipation device, including: a heat dissipation part with a heat dissipation structure formed on one surface thereof, the heat dissipation structure being configured to dissipate heat received from a heat-generating element; and a fluid inlet and outlet section disposed on the one surface of the heat dissipation part and provided with an inlet path and an outlet path, the inlet path being configured to receive fluid from both sides of the heat dissipation part and being formed with an inlet opening that is open towards the one surface of the heat dissipation part, the outlet path being formed with an outlet opening that is open towards the one surface of the heat dissipation part and is configured to discharge the fluid, wherein the fluid supplied from both directions of the fluid inlet and outlet section is supplied to the heat dissipation structure of the heat dissipation part through the inlet opening of the inlet path to absorb heat and is then discharged back into the fluid inlet and outlet section through the outlet opening of the outlet path.

The fluid inlet and outlet section may include a plurality of tunnel-shaped members, each having a through-channel with both ends open and with a lower surface of the through-channel open. The plurality of tunnel-shaped members may be arranged in parallel and spaced apart from each other on the one surface of the heat dissipation part so that the fluid is drawn in from both sides of the through-channel, forming an inlet path that allows the fluid to be supplied through the inlet opening formed in the lower surface of the through-channel. Between the plurality of tunnel-shaped members, the outlet opening may be formed on the one surface of the heat dissipation part to create the outlet path through which the fluid is discharged.

The tunnel-shaped member may include a pair of sidewalls extending along both sides of the heat dissipation part and a top wall connecting the pair of sidewalls and sealing an upper surface of the through-channel.

The heat dissipation structure may include a plurality of fins arranged parallel to each other on the one surface of the heat dissipation part, and the plurality of tunnel-shaped members may be arranged in a direction intersecting the plurality of fins, and the inlet opening may be formed in the through-channel of the tunnel-shaped member disposed in a space between the plurality of fins, and the outlet opening may be formed in a space between the plurality of fins exposed between the plurality of tunnel-shaped members.

The heat dissipation structure may include a plurality of pin-fins arranged spaced apart from each other on the one surface of the heat dissipation part, and the inlet opening may be formed in the through-channel of the tunnel-shaped member disposed in a space between the plurality of pin-fins, and the outlet opening may be formed in a space between the plurality of pin-fins exposed between the plurality of tunnel-shaped members.

According to an embodiment of the present disclosure, cold fluid may be evenly distributed and supplied to various locations on the heat dissipation part, and the fluid that has become hot by absorbing heat from the heat dissipation part may be rapidly discharged out of the heat dissipation part, forming a structure that facilitates effective heat dissipation.

Furthermore, a clear separation may be established between the path of the supplied cold fluid and the path of the heated fluid, and the discharge path for the heated fluid may be set with the shortest route, preventing the heated fluid from stagnating within the heat dissipation part.

### BRIEF DESCRIPTION OF THE DRAWINGS

FIG. 1 and FIG. 2 illustrate a heat dissipation device according to the prior art.

FIG. 3 illustrates a heat dissipation device according to an embodiment of the present disclosure.

FIG. 4 and FIG. 5 each illustrate a heat dissipation structure of the heat dissipation part.

FIGS. 6 through 8 each illustrate the heat dissipation structure in the heat dissipation device according to one aspect of the present disclosure.

FIGS. 9 and 10 illustrate a heat dissipation device according to another embodiment of the present disclosure.

FIGS. 11 through 13 illustrate a heat dissipation device according to yet another embodiment of the present disclosure.

FIGS. 14 and 15 illustrate a heat dissipation device according to still yet another embodiment of the present disclosure.

FIGS. 16 and 17 illustrate a heat dissipation device according to another different embodiment of the present disclosure.

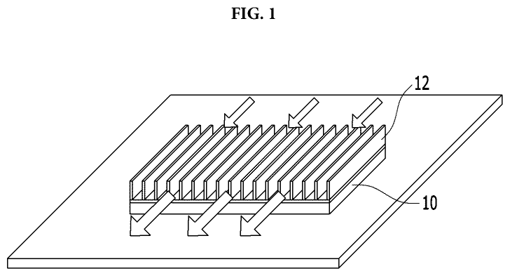

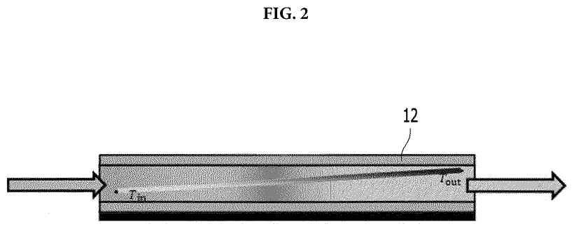

### DETAILED DESCRIPTION

The terminology used in this application is for the purpose of describing particular embodiments only and is not intended to limit the scope of the disclosure. Unless the context clearly indicates otherwise, singular terms are intended to include the plural.

In the present application, when a part is described to “include” a certain element, it shall mean that the part may not exclude but may include another element, unless specifically stated otherwise. Additionally, throughout the specification, the term “on” refers to being positioned either on top of or beneath the object in question, and it does not necessarily mean being positioned on the upper side relative to the gravitational direction.

Moreover, the term “coupling” refers to the relationship of contact between elements and is not limited to cases where the elements are in direct physical contact. The term also encompasses cases where another element is interposed between the elements, with each element being in contact with the interposed element.

Furthermore, terms such as “first,” “second,” etc., may be used to describe various elements, but these components shall not be limited by these terms. These terms are only used to distinguish one element from another.

The sizes and thicknesses of the elements shown in the drawings are depicted arbitrarily for convenience of explanation and shall not be construed as limiting the scope of the disclosure to the specific illustrations.

Hereinafter, certain embodiments of the heat dissipation device according to the present disclosure will be described in detail with reference to the accompanying drawings. In describing the embodiments with reference to the drawings, identical or corresponding elements are assigned the same reference numerals, and redundant descriptions thereof will be omitted.

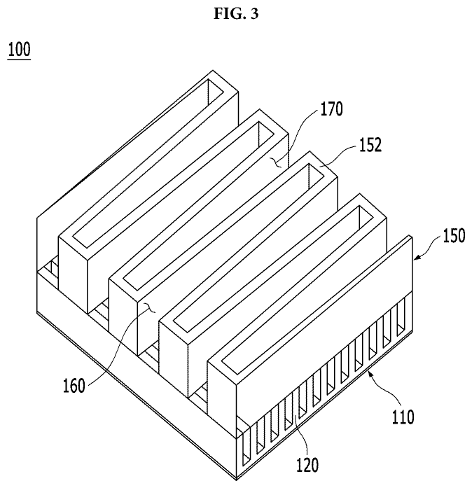

FIG. 3 illustrates a heat dissipation device according to one embodiment of the present disclosure. Referring to FIG. 3, the heat dissipation device 100 according to one embodiment of the present disclosure includes a heat dissipation part 110 and a fluid inlet and outlet section 150. The heat dissipation part 110 is configured to receive heat from a heat-generating element (e.g., an electronic device, etc.) and dissipate the received heat to the outside. The heat dissipation part 110 has a heat dissipation structure 120, 130 formed on one surface thereof that is configured for dissipating the heat. In the heat dissipation part 110 of the present embodiment, the heat dissipation structure 120, 130 may include a plurality of fins 120 or a plurality of pin-fins 130 formed on one surface of the heat dissipation part 110.

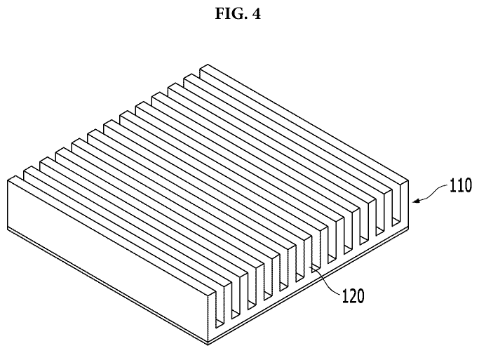

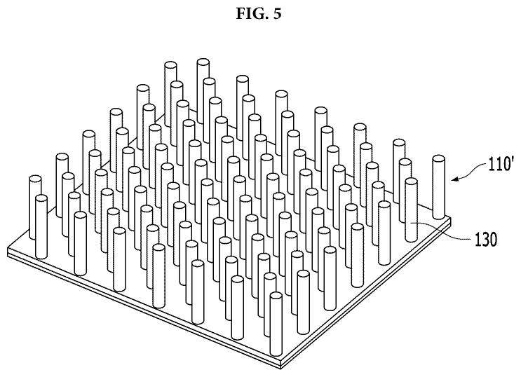

FIGS. 4 and 5 illustrate the heat dissipation structure 120, 130 of the heat dissipation part 110. Referring to FIG. 4, a plurality of fins 120 may be arranged in parallel and upright on one surface of the heat dissipation part 110. Additionally, referring to FIG. 5, a plurality of pin-fins 130 may be arranged upright and spaced apart from each other in regular intervals on one surface of the heat dissipation part 110. The plurality of pin-fins 130 and the plurality of fins 120 may increase the surface area of the heat dissipation part 110, thereby enhancing contact between external fluid and the heat dissipation part 110. As a result, the heat received from the heat-generating element may be distributed and dispersed among the plurality of pin-fins 130 or the plurality of fins 120, and the dispersed heat may be effectively dissipated into cooling fluid through the plurality of pin-fins 130 or the plurality of fins 120.

The fluid inlet and outlet section 150 forms a path for supplying and discharging fluid to ensure effective heat dissipation in the heat dissipation part 110. The fluid inlet and outlet section 150 is disposed on one surface of the heat dissipation part 110, where the heat dissipation structure 120, 130 is formed, and includes an inlet path 160 for supplying fluid and an outlet path 170 for discharging fluid.

The inlet path 160 may be formed with an inlet opening 162 that is open toward one surface of the heat dissipation part 110. Accordingly, a path through which fluid is supplied at positions advantageous for heat transfer may be formed on the surface of the heat dissipation part 110. Moreover, this configuration may facilitate the formation of paths that allow fluid to be divided and supplied at various positions on the surface of the heat dissipation part 110.

Moreover, the outlet path 170 may be formed with an outlet opening 172 that is open toward one surface of the heat dissipation part 110. Accordingly, a path through which fluid that has absorbed heat from the heat dissipation part 110 is immediately discharged may be formed. Moreover, paths that allow fluid to be divided and discharged at various positions on the one surface of the heat dissipation part 110 may be easily formed.

Thus, the fluid supplied to the fluid inlet and outlet section 150 may be directed through the inlet opening 162 of the inlet path 160 to the heat dissipation structure 120, 130 of the heat dissipation part 110 to absorb heat and then discharged through the outlet opening 172 of the outlet path 170 back into the fluid inlet and outlet section 150.

Referring to FIGS. 3 and 4, the fluid inlet and outlet section 150 of the present embodiment may have a stacked structure on one surface of the heat dissipation part 110. When the heat dissipation part 110 has a structure in which a plurality of fins 120 are arranged upright in parallel on one surface, the fluid inlet and outlet section 150 may take the form of a block structure directly stacked on top of the plurality of fins 120.

In such a case, the fluid inlet and outlet section 150 may have a structure in which the inlet path 160 and the outlet path 170 are separated by a partition wall 152. This allows the cold fluid entering the heat dissipation part 110 and the hot fluid being discharged from the heat dissipation part 110 to flow in and be separated along distinct paths.

Particularly, the fluid inlet and outlet section 150 may be provided with a plurality of inlet paths 160 and a plurality of outlet paths 170, and the plurality of inlet paths 160 and the plurality of outlet paths 170 may be arranged in an alternating structure. Accordingly, it is possible to form paths that allow the fluid to be evenly distributed and introduced to multiple locations of the heat dissipation part 110 and to be discharged from multiple locations.

Specifically, in the present embodiment, the partition wall 152 of the fluid inlet and outlet section 150 positioned on top of the heat dissipation part 110 may be formed in a zigzag structure to separate the plurality of inlet paths 160 and the plurality of outlet paths 170. As a result, the plurality of inlet paths 160 and the plurality of outlet paths 170 may be alternately arranged adjacent to each other. On top of the plurality of fins 120, the partition wall 152 may be formed in a zigzag manner in a crossing direction of the fins 120.

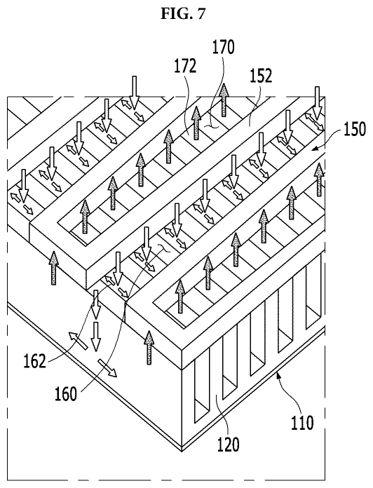

In such a case, the inlet paths 160 and outlet paths 170 may have a structure with the bottom surfaces thereof penetrating through to form the inlet openings 162 (see FIG. 7) and the outlet openings 172 (see FIG. 7) from the inlet paths 160 and outlet paths 170 to the heat dissipation part 110. While the present embodiment presents the fluid inlet and outlet section 150 as having a fully penetrating bottom surface except for the partition wall 152, the present disclosure is not limited to this configuration, and the inlet openings 162 and the outlet openings 172 may include various forms that partially penetrate the bottom surface of the fluid inlet and outlet section 150.

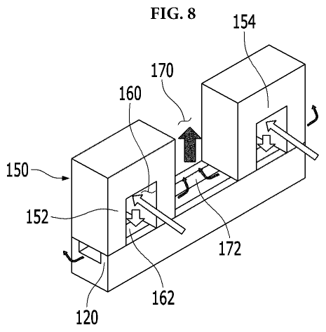

Meanwhile, the fluid inlet and outlet section 150 may further include a cover 154 (see FIG. 8) that covers at least one of the inlet path 160 and the outlet path 170 to prevent the fluid in the inlet paths 160 and outlet paths 170 from mixing with each other.

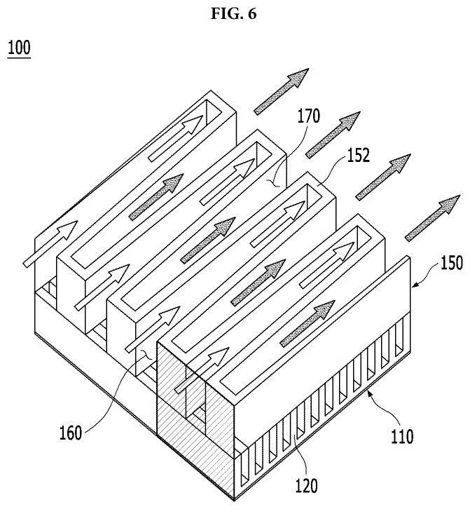

FIGS. 6 to 8 are diagrams illustrating the heat dissipation structure in a heat dissipation device 100 according to an aspect of the present disclosure. Referring to FIGS. 6 to 8, the fluid inlet and outlet section 150 of the present embodiment may be provided with a zigzag-structured partition wall 152, forming a plurality of inlet paths 160 that allow fluid to be evenly distributed and introduced to one side of the fluid inlet and outlet section 150. In each inlet path 160, the fluid can move downward through the inlet openings 162, which penetrate the bottom surface, and be supplied between the fins 120 of the heat dissipation part 110. Here, a cover 154 may be formed to cover the upper surface of the inlet paths 160 to facilitate the downward movement of the fluid.

The fluid supplied between the fins 120 may absorb heat as it moves along the gaps between the fins 120 and reach the outlet openings 172 of the adjacent outlet paths 170. Upon reaching the outlet openings 172, the fluid may move upward through the outlet openings 172 and be evenly discharged through the plurality of outlet paths 170 toward the opposite side of the fluid inlet and outlet section 150.

Therefore, according to the present embodiment, the cold fluid may be evenly distributed and supplied at multiple locations on the heat dissipation part 110, and the fluid, which has absorbed heat and become hot, may be quickly discharged outside the heat dissipation part 110, forming an effective heat dissipation structure. Particularly, a clear separation may be established between the path of the incoming cold fluid and the path of the outgoing hot fluid, and the outlet paths 170 for the heated fluid may be set to the shortest possible route, preventing the stagnation of heated fluid within the heat dissipation part 110.

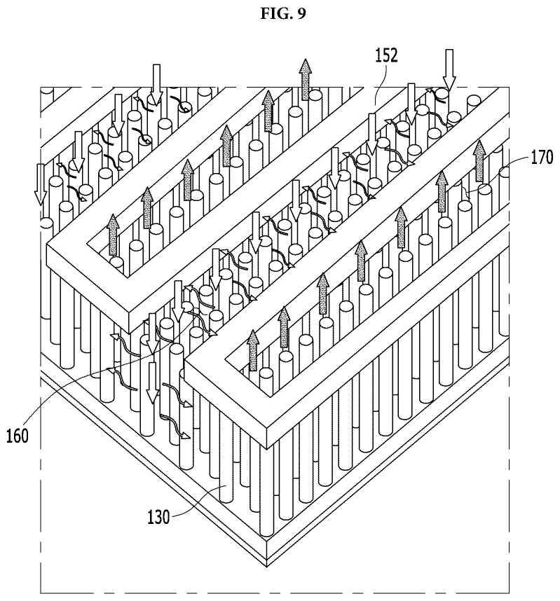

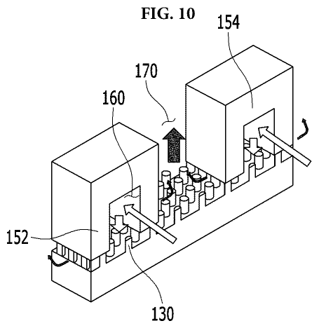

FIGS. 9 and 10 illustrate a heat dissipation device according to another embodiment of the present disclosure. Referring to FIGS. 9 and 10, the heat dissipation device according to the present embodiment is configured to apply the above-described fluid inlet and outlet section 150 to a heat dissipation part 110 in which a plurality of pin-fins 130 are arranged upright and spaced apart in regular intervals. The heat dissipation structure, functions, and effects in the present embodiment may be similar to those described above.

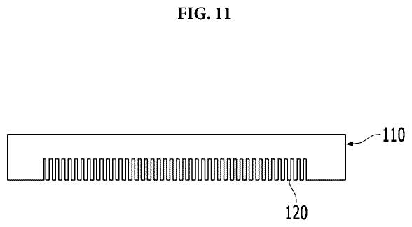

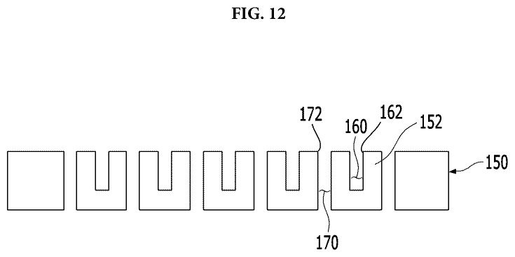

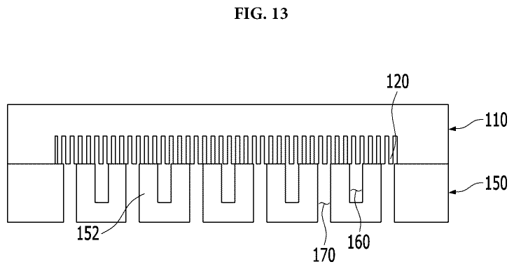

FIGS. 11 to 13 illustrate a heat dissipation device according to yet another embodiment of the present disclosure. Referring to FIGS. 11 to 13, the heat dissipation device according to the present embodiment specifically illustrates a structure in which the heat dissipation device is applied to an electronic device. The heat dissipation part 110 of the present embodiment includes a heat sink having a heat dissipation structure 120, 130, such as a plurality of fins 120, formed on one surface thereof and having an electronic device attached to the other surface thereof. The fluid inlet and outlet section 150 may have a plate structure corresponding to the heat sink and may be structured to attach to one surface of the heat sink. For example, the heat sink may be formed with a silicon (Si) substrate, and the heat dissipation structure 120, 130 may be formed by etching one surface of the Si substrate. Moreover, the fluid inlet and outlet section 150 may be formed with a glass substrate that is attached to the heat sink, and the inlet paths 160, the outlet paths 170, the inlet openings 162, and the outlet openings 172 may be formed by etching the glass substrate.

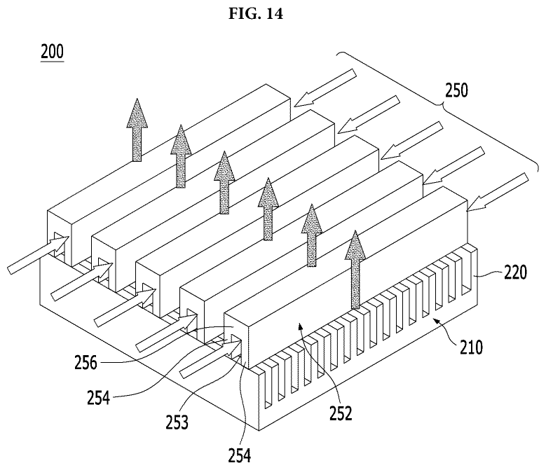

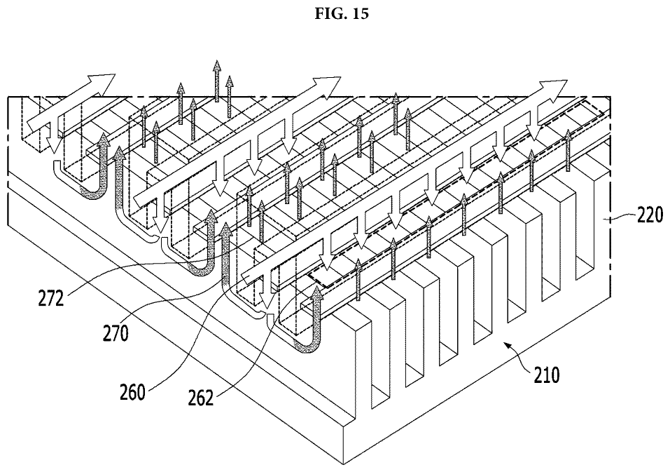

FIGS. 14 and 15 illustrate a heat dissipation device according to still yet another embodiment of the present disclosure. Referring to FIGS. 14 and 15, a heat dissipation device 200 according to still yet another embodiment of the present disclosure includes a heat dissipation part 210 and a fluid inlet and outlet section 250. The heat dissipation part 210 is configured to receive heat from a heat-generating element (e.g., an electronic device, etc.) and dissipate the received heat to the outside. The heat dissipation part 210 has a heat dissipation structure 220, 230, which is configured for dissipating the heat, formed on one surface thereof. A plurality of fins 220 may be arranged upright and in parallel on one surface of the heat dissipation part 210. The plurality of fins 220 may be spaced apart from each other, forming spaces between the fins 220 and in parallel with the fins 220.

The fluid inlet and outlet section 250 forms a path for supplying and discharging fluid to ensure effective heat dissipation in the heat dissipation part 210. The fluid inlet and outlet section 250 is disposed on one surface of the heat dissipation part 210, where the heat dissipation structure 220, 230 is formed, and is formed with an inlet path 260 for supplying fluid and an outlet path 270 for discharging fluid. The inlet path 260 may be formed with an inlet opening 262 that is open toward one surface of the heat dissipation part 210. Similarly, the outlet path 270 may be formed with an outlet opening 272 that is open toward one surface of the heat dissipation part 210.

Particularly, the fluid inlet and outlet section 250 of the present embodiment may have a structure in which fluid is simultaneously supplied from both directions. In other words, the inlet path 260 of the fluid inlet and outlet section 250 may be designed to have fluid supplied simultaneously from both sides of the heat dissipation part 210. Accordingly, it is possible to rapidly supply a large volume of fluid to the inlet path 260. Moreover, it is possible to directly supply fluid through the shortest path on one surface of the heat dissipation part 210, and it is possible to easily forma paths that distribute fluid at multiple locations on one surface of the heat dissipation part 210.

Referring to FIGS. 14 and 15, the fluid inlet and outlet section 250 of the present embodiment may include a plurality of tunnel-shaped members 252. The tunnel-shaped members 252 may have through-channels 253 formed therein, with both ends open. For example, the tunnel-shaped members 252 may be formed in a linear shape and arranged to traverse the heat dissipation part 210. Accordingly, it is possible to form a structure in which fluid is drawn into the through-channels 253 of the tunnel-shaped members 252 from both sides of the heat dissipation part 210. Moreover, the through-channels 253 within the tunnel-shaped members 252 may have a form that the bottoms thereof are open. Accordingly, it is possible to supply the fluid drawn into the through-channels 253 of the tunnel-shaped members 252 to the directly below heat dissipation part 210 via the shortest path.

The plurality of tunnel-shaped members 252 may also be arranged in parallel and spaced apart from each other on one surface of the heat dissipation part 210. For instance, the plurality of linearly shaped tunnel-shaped members 252 may be arranged in multiple rows so that the through-channels 253 are aligned in parallel with a consistent spacing therebetween. Accordingly, it is possible to allow fluid to be divided and drawn into the plurality of tunnel-shaped members 252 from both sides of the heat dissipation part 210. Therefore, through the tunnel-shaped members 252, it is possible to have the fluid to be drawn into both sides of the through-channels 253 and have inlet openings 262 formed on the bottom surface of the through-channels 253, thereby forming the inlet path 260 through which fluid is quickly supplied to the heat dissipation part 210.

Meanwhile, the spaces between the plurality of fins 220 may serve as the outlet paths 270. In such a case, outlet openings 272 that are open upward toward one surface of the heat dissipation part 210 may be formed in the outlet paths 270. Accordingly, it is possible to form a path in which the fluid that has absorbed heat from the heat dissipation part 210 rises and is discharged directly. Additionally, it is possible to easily form paths that allow fluid to be divided and discharged from multiple locations on one surface of the heat dissipation part 210.

Particularly, in the present embodiment, outlet openings 272 may be formed between the plurality of tunnel-shaped members 252. Since there are gaps formed between the plurality of tunnel-shaped members 252, the spaces between the plurality of fins 220 may be exposed. The outlet openings 272 may be formed in the exposed spaces between the plurality of fins 220.

Referring to FIGS. 14 and 15, the tunnel-shaped members 252 in the present embodiment may include a pair of sidewalls 254 extending to both sides of the heat dissipation part 210 and a top wall 256 connecting the pair of sidewalls 254 and sealing the upper surface of the through-channel 253. The plurality of tunnel-shaped members 252 may be arranged in a direction intersecting the plurality of fins 220. Accordingly, the through-channels 253 of the tunnel-shaped members 252 that are positioned between the plurality of fins 220 may be open between the plurality of fins 220 to form inlet openings 262 through which fluid is supplied. Moreover, the spaces between the plurality of fins 220 may be exposed between the plurality of tunnel-shaped members 252 to form outlet openings 272 through which fluid is discharged.

Therefore, the heat dissipation device 200 of the present embodiment may provide a fluid flow path that allows a large volume of fluid to be simultaneously drawn in from both sides of the heat dissipation part 210, supplied to the heat dissipation part 210 through the inlet openings 262 directly below, and then discharged upward through the outlet openings 272 adjacent to the inlet openings 262 after being heated in the heat dissipation part 210. This configuration enables the formation of the shortest possible fluid flow paths required for heat dissipation. By providing the shortest fluid flow paths, it is possible to minimize pressure build-up and improve energy efficiency.

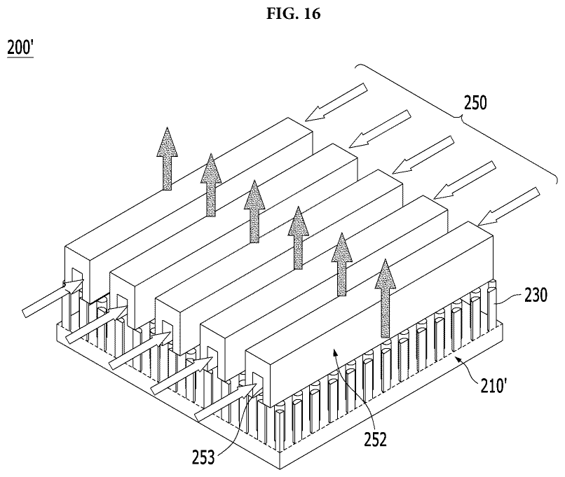

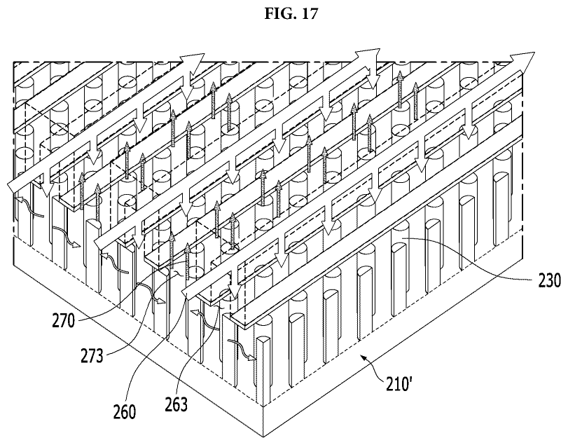

FIGS. 16 and 17 illustrate a heat dissipation device according to another different embodiment of the present disclosure. Referring to FIGS. 16 and 17, the heat dissipation device 200′ according to present embodiment is configured to apply the above-described fluid inlet and outlet section 250 to a heat dissipation part 210′ in which a plurality of pin-fins 230 are arranged upright and spaced apart from each other in regular intervals. The heat dissipation structure, functions, and effects in the present embodiment may be similar to those described above. In the present embodiment, the heat dissipation structure 230 may include a plurality of pin-fins 230 arranged to be spaced apart from each other on one surface of the heat dissipation part 210′, in which case inlet openings 263 may be formed the through-channel 253 of the tunnel-shaped member 252 that is positioned between the plurality of pin-fins 230. Moreover, outlet openings 273 may be formed in the spaces between the plurality of pin-fins 230 that are exposed between the plurality of tunnel-shaped members 252.

Hitherto, the foregoing description of preferred embodiments of the present disclosure has been provided. However, it should be understood that a person of ordinary skill in the art could make various modifications and changes to the present disclosure without departing from the spirit of the present disclosure as set forth in the appended claims. Such modifications, including the addition, alteration, deletion, or supplementation of components, are intended to be included within the scope of the present disclosure.

### DESCRIPTION OF ELEMENTS

100, 200, 200′: heat dissipation device
110, 110′, 210, 210′: heat dissipation part
120, 220: fin
130, 230: pin-fin
150, 250: fluid inlet and outlet section
152: partition wall
154: cover
160, 260: inlet path
162, 262: inlet opening
170, 270: outlet path
172, 272: outlet opening
252: tunnel-shaped member

1. A heat dissipation device comprising:
a heat dissipation part with a heat dissipation structure formed on one surface thereof, the heat dissipation structure being configured to dissipate heat received from a heat-generating element; and
a fluid inlet and outlet section disposed on the one surface of the heat dissipation part and provided with an inlet path and an outlet path, the inlet path being configured to receive fluid from both sides of the heat dissipation part and being formed with an inlet opening that is open towards the one surface of the heat dissipation part, the outlet path being formed with an outlet opening that is open towards the one surface of the heat dissipation part and is configured to discharge the fluid,
wherein the fluid supplied from both directions of the fluid inlet and outlet section is supplied to the heat dissipation structure of the heat dissipation part through the inlet opening of the inlet path to absorb heat and then discharged through the outlet opening of the outlet path back into the fluid inlet and outlet section.

2. The heat dissipation device according to claim 1, wherein the fluid inlet and outlet section comprises a plurality of tunnel-shaped members, each having a through-channel with both ends open and with a bottom surface of the through-channel open, and
wherein the plurality of tunnel-shaped members are arranged in parallel and spaced apart from each other on the one surface of the heat dissipation part, such that the fluid is drawn in from both sides of the through-channel, forming an inlet path that allows the fluid to be supplied through the inlet opening formed in the bottom surface of the through-channel, and the outlet opening is formed between the plurality of tunnel-shaped members on the one surface of the heat dissipation part to create the outlet path through which the fluid is discharged.

3. The heat dissipation device according to claim 2, wherein the tunnel-shaped members each comprise:
a pair of sidewalls extending to both sides of the heat dissipation part; and
a top wall connecting the pair of sidewalls and sealing an upper surface of the through-channel.

4. The heat dissipation device according to claim 2, wherein the heat dissipation structure comprises a plurality of fins arranged in parallel and spaced apart from each other on the one surface of the heat dissipation part,
wherein the plurality of tunnel-shaped members are arranged in a direction intersecting the plurality of fins,
wherein the inlet opening is formed in the through-channel of the tunnel-shaped member disposed in a space between the plurality of fins, and
wherein the outlet opening is formed in a space between the plurality of fins exposed between the plurality of tunnel-shaped members.

5. The heat dissipation device according to claim 2, wherein the heat dissipation structure comprises a plurality of pin-fins arranged spaced apart from each other on the one surface of the heat dissipation part,
wherein the inlet opening is formed in the through-channel of the tunnel-shaped member disposed in a space between the plurality of pin-fins, and
wherein the outlet opening is formed in a space between the plurality of pin-fins exposed between the plurality of tunnel-shaped members.
